(19) United States
(12) Patent Application Publication
(10) Pub. No.: US 2026/0324384 A1
(43) Pub. Date: Oct. 15, 2026

(54) SEMICONDUCTOR CHIP AND SEMICONDUCTOR PACKAGE INCLUDING SUBSTRATE

(71) Applicant: SK hynix Inc., Icheon-si Gyeonggi-do (KR)

(72) Inventor: Ji Ho PARK, Icheon-si Gyeonggi-do (KR)

(73) Assignee: SK hynix Inc., Icheon-si Gyeonggi-do (KR)

(21) Appl. No.: 19/399,043

(22) Filed: Nov. 24, 2025

(30) Foreign Application Priority Data
Apr. 10, 2025 (KR) 10-2025-0046527

(51) Int. Cl. H10W 20/20; H10W 40/25; H10W 90/00; H10W 90/20; H10W 90/26

(52) U.S. Cl. CPC H10W 20/20; H10W 40/255; H10W 90/00; H10W 90/26; H10W 90/297; H10W 90/722; H10W 90/792

(57) ABSTRACT

A semiconductor chip includes a first substrate having a first coefficient of thermal expansion. A circuit structure is disposed on the first substrate. A second substrate is disposed on the circuit structure. The second substrate has a second coefficient of thermal expansion in a range of 0.8 to 1.2 times the first coefficient of thermal expansion.

### CROSS REFERENCE TO RELATED APPLICATION

The present application claims priority under 35 U.S.C. §119(a) to Korean patent application number 10-2025-0046527 filed in the Korean Intellectual Property Office on Apr. 10, 2025, which application is incorporated herein by reference in its entirety.

### BACKGROUND

### 1. Technical Field

The present disclosure relates to a semiconductor chip and a semiconductor package including a substrate.

### 2. Related Art

A semiconductor package includes a semiconductor chip having a circuit structure on a substrate. The circuit structure typically includes metal wirings and insulating layers.

A chip stacking package is a semiconductor package that expands functions and increases capacity and integration by stacking multiple semiconductor chips. A TSV stacking package is a chip stacking package that forms at least one through silicon via (TSV) on a semiconductor chip and electrically connects the semiconductor chips to each other using the TSVs.

### SUMMARY

An embodiment of a semiconductor chip may include a first substrate having a first coefficient of thermal expansion, a circuit structure on the first substrate, and a second substrate disposed on the circuit structure and having a second coefficient of thermal expansion in a range of 0.8 to 1.2 times the first coefficient of thermal expansion.

An embodiment of a semiconductor package may include a base chip, a core chip on the base chip, and a top chip on the core chip. The core chip may include a first substrate having a first coefficient of thermal expansion, a circuit structure on the first substrate, and a second substrate disposed on the circuit structure and having a second coefficient of thermal expansion in a range of 0.8 to 1.2 times the first coefficient of thermal expansion.

An embodiment of a semiconductor package may include a plurality of semiconductor chips stacked sequentially, wherein each of the plurality of semiconductor chips may include a first substrate having a first coefficient of thermal expansion, a circuit structure on the first substrate, and a second substrate disposed on the circuit structure and having a second coefficient of thermal expansion in a range of 0.8 to 1.2 times the first coefficient of thermal expansion.

### BRIEF DESCRIPTION OF THE DRAWINGS

FIG. 1 is a cross-sectional view of a semiconductor chip according to an embodiment of the present disclosure.

FIGS. 2 to 5 are partial views of a semiconductor chip according to an embodiment of the present disclosure.

FIGS. 6 and 7 are cross-sectional views of a semiconductor package according to an embodiment of the present disclosure.

FIGS. 8 to 19 are cross-sectional views of a semiconductor package formed utilizing a method of forming a semiconductor chip and a semiconductor package according to an embodiment of the present disclosure.

FIGS. 20 to 26 are cross-sectional views of a semiconductor package formed utilizing a method of forming a semiconductor chip and a semiconductor package according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” to another element, the elements may be connected directly or through an intervening element between the elements. When two elements are identified as “directly connected,” one element is directly connected to the other element without an intervening element between the two elements.

When one element is identified as “on” another element, the elements may directly contact each other or an intervening element may be disposed between the elements.

Terms such as “vertical,” “horizontal,” “top,” “bottom,” “on,” “side,” “upper,” “lower,” “rear,” “high,” “overlap,” and other terms implying relative spatial relationship or orientation are utilized only for the purpose of ease of description or reference to a drawing and are not otherwise limiting.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

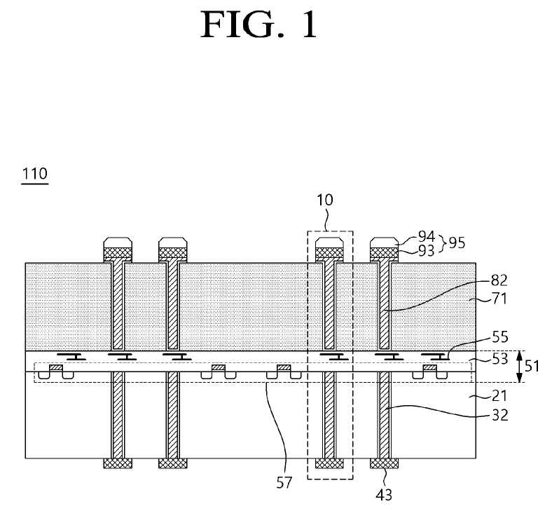

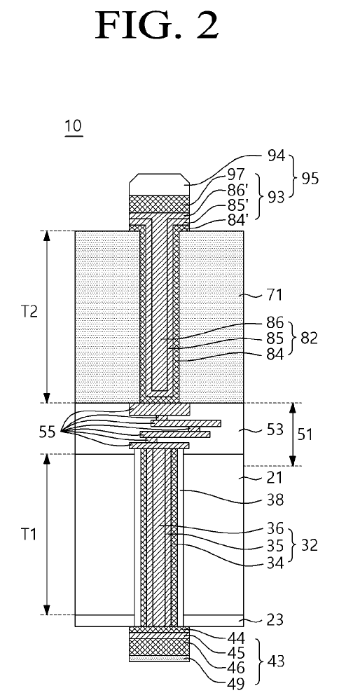

FIG. 1 is a cross-sectional view illustrating a semiconductor chip according to an embodiment of the present disclosure, and FIGS. 2 to 5 are partial views. In an embodiment, FIGS. 2 to 4 are partial views illustrating a section 10 of FIG. 1.

Referring to FIG. 1, a semiconductor chip 110 according to an embodiment of the present disclosure includes a first substrate 21, a first through-electrode 32, a first bump 43, a circuit structure 51, a second substrate 71, a second through-electrode 82, and a second bump 95.

The circuit structure 51 is disposed on the first substrate 21. The second substrate 71 is disposed on the circuit structure 51. The first through-electrode 32 extends through the first substrate 21 in a vertical direction and is connected to the first bump 43 and the circuit structure 51. The first bump 43 is disposed on a lower surface of the first substrate 21. The first bump 43 overlaps or is aligned with with the first through-electrode 32 in a vertical direction. The first bump 43 contacts the first through-electrode 32.

The circuit structure 51 includes an interlayer insulating layer 53, a plurality of horizontal/vertical wirings 55, and an integrated circuit 57. The plurality of horizontal/vertical wirings 55 are arranged within the interlayer insulating layer 53. The plurality of horizontal/vertical wirings 55 are electrically connected to the integrated circuit 57. One of the plurality of horizontal/vertical wirings 55 contacts the first through-electrode 32. The wirings and insulating layers in the circuit structure 51 may include a material having a different thermal expansion coefficient from the thermal expansion coefficient of the substrate 51. The integrated circuit 57 is formed on the first substrate 21. The integrated circuit 57 is covered with or disposed within the interlayer insulating layer 53. The integrated circuit 57 may be implemented in various ways depending on the type of the semiconductor chip 110. In an embodiment, the semiconductor chip 110 is a memory chip, and the integrated circuit 57 includes a memory cell. The memory may be a volatile memory or a nonvolatile memory. The volatile memory may be DRAM (Dynamic Random Access Memory) and SRAM (Static Random Access Memory). The nonvolatile memory may be NAND, NOR, PRAM (Phase Change Random Access Memory) and MRAM (Magneto-Resistive Random Access Memory). In an embodiment, the semiconductor chip 110 is a logic chip that controls the memory chip, and the integrated circuit 57 includes a logic transistor that controls the memory chip.

The second through-electrode 82 extends through the second substrate 71 in a vertical direction and is connected to the second bump 95 and the circuit structure 51. The second through-electrode 82 contacts one of the plurality of horizontal/vertical wires 55. In an embodiment, the second through-electrode 82 overlaps with or is aligned with the first through-electrode 32 in a vertical direction. The second bump 95 is disposed on the upper surface of the second substrate 71. The second bump 95 overlaps with or is aligned with the second through-electrode 82 in a vertical direction. The second bump 95 contacts the second through-electrode 82. In an embodiment, the second bump 95 overlaps with or is aligned with the first bump 43 in a vertical direction. The second bump 95 includes a metal pillar 93 and a solder layer 94. The metal pillar 93 is disposed on the upper surface of the second substrate 71 and is connected to the second through-electrode 82. The solder layer 94 is disposed on the upper surface of the metal pillar 93.

Referring to FIG. 2, a rear insulating layer 23 is disposed on the lower surface of the first substrate 21. The first through-electrode 32 vertically extends through the first substrate 21 and the rear insulating layer 23 and contacts the first bump 43. One end of the first through-electrode 32 extends into the interlayer insulating layer 53 and is connected to one of the plurality of horizontal/vertical wirings 55. A height of the first through-electrode 32 is larger than a horizontal width of the first through-electrode 32.

A first spacer 38 is disposed on a side surface of the first through-electrode 32. The first spacer 38 may surround the side surface of the first through-electrode 32. The first through-electrode 32 includes a first barrier layer 34, a first seed layer 35, and a first conductive layer 36. The first seed layer 35 surrounds a side surface of the first conductive layer 36. The first barrier layer 34 surrounds a side surface of the first seed layer 35. The first seed layer 35 is interposed between the first barrier layer 34 and the first conductive layer 36.

The first bump 43 is disposed on the lower surface of the rear insulating layer 23. The first bump 43 includes a first bump barrier layer 44, a first bump seed layer 45, a first bump conductive layer 46, and a bump capping layer 49 that are sequentially stacked. The first bump barrier layer 44 contacts the first through-electrode 32.

The second through-electrode 82 extends through the second substrate 71 in a vertical direction and is connected to one of a plurality of horizontal/vertical wirings 55. A height of the second through-electrode 82 is larger than the horizontal width of the second through-electrode 82. The second through-electrode 82 includes a second barrier layer 84, a second seed layer 85, and a second conductive layer 86. The second seed layer 85 surrounds a side surface and a bottom surface of the second conductive layer 86. The second barrier layer 84 surrounds the side surface and a bottom surface of the second seed layer 85. The second seed layer 85 is interposed between the second barrier layer 84 and the second conductive layer 86.

A second metal pillar 93 is disposed on the second substrate 71. The second metal pillar 93 includes a second bump barrier layer 84’, a second bump seed layer 85’, a second bump lower conductive layer 86’, and a second bump upper conductive layer 97. The second bump barrier layer 84’ is disposed on the second substrate 71. The second bump barrier layer 84’ is continuous with or singularly formed with the second barrier layer 84. A second bump seed layer 85’ is disposed on the second bump barrier layer 84’. The second bump seed layer 85’ is continuous with or singularly formed with the second seed layer 85. The second bump lower conductive layer 86’ is disposed on the second bump seed layer 85’. The second bump lower conductive layer 86’ is continuous with or singularly formed with the second conductive layer 86. A second bump upper conductive layer 97 is disposed on the second bump lower conductive layer 86’.

Referring to FIGS. 1 and 2, the first substrate 21 includes a semiconductor substrate, such as a silicon wafer or a silicon-on-insulator (SOI) wafer. The first substrate 21 may include an III-V group semiconductor substrate, for example, a compound semiconductor substrate, such as GaAs. In an embodiment, the first substrate 21 may include single crystal silicon. The first substrate 21 may have a first coefficient of thermal expansion at 20°C to 300°C. In an embodiment, the first coefficient of thermal expansion of the first substrate 21 is 2.5 ppm/°C to 3.6 ppm/°C.

The circuit structure 51 may include a material having a greater coefficient of thermal expansion than the coefficient of thermal expansion of the first substrate 21. In an embodiment, the plurality of horizontal/vertical wirings 55 and the integrated circuit 57 may include a metal layer. In an embodiment, the plurality of horizontal/vertical wirings 55 and the integrated circuit 57 include a material having a greater coefficient of thermal expansion than the coefficient of thermal expansion of the first substrate 21.

The second substrate 71 may have a second coefficient of thermal expansion at 20°C to 300°C. The second coefficient of thermal expansion may have a value in the range of 0.8 to 1.2 times the first coefficient of thermal expansion. In an embodiment, the second coefficient of thermal expansion of the second substrate 71 may be 2.0 ppm/°C to 4.3 ppm/°C. In an embodiment, the second coefficient of thermal expansion of the second substrate 71 may be substantially the same as the first coefficient of thermal expansion of the first substrate 21. In an embodiment, the plurality of horizontal/vertical wirings 55 and the integrated circuit 57 may include a material having a greater coefficient of thermal expansion than the second substrate 71. In an embodiment, the second substrate 71 may include an inorganic insulating material. The inorganic insulating material may include silicon nitride, silicon oxide, or a combination thereof.

The first substrate 21 has a first thickness T1 in a first direction. In an embodiment, the first thickness T1 of the first substrate 21 is larger than a thickness of the circuit structure 51 in the first direction. The second substrate 71 has a second thickness T2 in the first direction. The second thickness T2 may have a value in the range of 0.2 to 1.2 times the first thickness T1. In an embodiment, the second thickness T2 may be substantially the same as the first thickness T1. The second thickness T2 is larger than the thickness of the circuit structure 51 in the first direction.

Due to the difference in coefficient of thermal expansion, the semiconductor chip 110 including the first substrate 21 and the circuit structure 51 may experience physical deformation such as warping or bending during a semiconductor process. The second substrate 71 may prevent or reduce physical deformation of the semiconductor chip 110.

The first barrier layer 34, the first bump barrier layer 44, the second barrier layer 84, and the second bump barrier layer 84’ may include titanium (Ti), titanium nitride (TiN), tantalum (Ta), tantalum nitride (TaN), or a combination thereof. The first seed layer 35, the first bump seed layer 45, the second seed layer 85, and the second bump seed layer 85’ may include a conductive material such as copper. The first seed layer 35, the first bump seed layer 45, the second seed layer 85, and the second bump seed layer 85’ may be formed using a PVD method.

The first conductive layer 36, the second conductive layer 86, and the second bump lower conductive layer 86’ may include a conductive material such as copper. The first conductive layer 36, the first bump conductive layer 46, the second conductive layer 86, and the second bump lower conductive layer 86’ may be formed using an electrolytic plating method. The first bump conductive layer 46 and the second bump upper conductive layer 97 may include a conductive material such as nickel (Ni) or copper. The solder layer 94 may include tin (Sn), silver (Ag), copper (Cu), bismuth (Bi), indium (In), zinc (Zn), gold (Au), palladium (Pd), antimony (Sb), or a combination thereof. The first bump conductive layer 46, the second bump upper conductive layer 97, and the solder layer 94 may be formed using an electrolytic plating method.

The bump capping layer 49 may include gold (Au). The plurality of horizontal/vertical wirings 55 may include a conductive material such as a metal, a metal oxide, a metal nitride, a metal silicide, polysilicon, a conductive carbon, or a combination thereof.

The rear insulating layer 23, the first spacer 38, and the interlayer insulating layer 53 may include at least two materials selected from a group consisting of Si, O, N, C, B, P, and H. The rear insulating layer 23, the first spacer 38, and the interlayer insulating layer 53 may include silicon oxide, silicon nitride, silicon oxynitride, low-K dielectrics, high-K dielectrics, or a combination thereof.

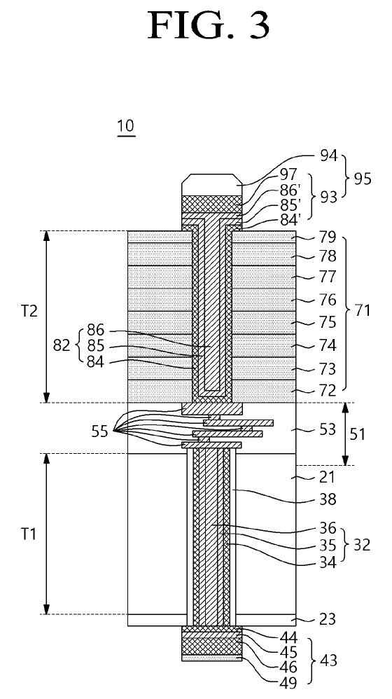

Referring to FIG. 3, the second substrate 71 may include a plurality of insulating layers 72, 73, 74, 75, 76, 77, 78 and 79. In an embodiment, the plurality of insulating layers 72, 73, 74, 75, 76, 77, 78 and 79 include a first insulating layer to an eighth insulating layer. The insulating layers 72, 73, 74, 75, 76, 77, 78 and 79 may be sequentially laminated or stacked on the circuit structure 51. In an embodiment, each of the insulating layers 72, 73, 74, 75, 76, 77, 78 and 79 have substantially the same thickness. In an embodiment, the insulating layers 72, 73, 74, 75, 76, 77, 78 and 79 have different thicknesses. In an embodiment, the eighth insulating layer 79 has a thickness smaller than each of the first insulating layer to the seventh insulating layer 72, 73, 74, 75, 76, 77 and 78. The eighth insulating layer 79 is an uppermost layer of the insulating layers 72, 73, 74, 75, 76, 77, 78 and 79.

In an embodiment, the insulating layers 72, 73, 74, 75, 76, 77, 78 and 79 include substantially the same material layer. Each of the insulating layers 72, 73, 74, 75, 76, 77, 78 and 79 may include a material having a second coefficient of thermal expansion. In an embodiment, each of the insulating layers 72, 73, 74, 75, 76, 77, 78 and 79 may include silicon nitride.

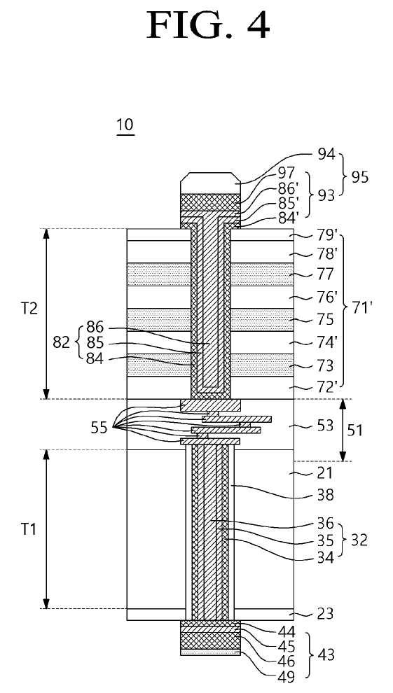

Referring to FIG. 4, the second substrate 71’ includes the insulating layers 72’, 73, 74’, 75, 76’, 77, 78’ and 79’. Each of the insulating layers 72’, 73, 74’, 75, 76’, 77, 78’ and 79’ may include a material having a second coefficient of thermal expansion. In an embodiment, some of the insulating layers 72’, 73, 74’, 75, 76’, 77, 78’ and 79’ may include a material different from the other layers. The first insulating layer 72’, a third insulating layer 74’, a fifth insulating layer 76’, a seventh insulating layer 78’, and the eighth insulating layer 79’ may include a material different from a second insulating layer 73, a fourth insulating layer 75, and a sixth insulating layer 77. The first insulating layer 72’, the third insulating layer 74’, the fifth insulating layer 76’, the seventh insulating layer 78’, and the eighth insulating layer 79’ may include silicon oxide. The second insulating layer 73, the fourth insulating layer 75, and the sixth insulating layer 77 may include silicon nitride.

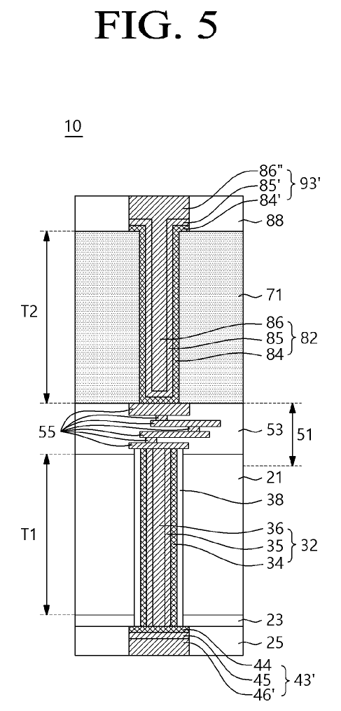

Referring to FIG. 5, a first pad 43’ is disposed on the lower surface of the rear insulating layer 23. The first pad 43’ is connected to the first through-electrode 32. A first bonding insulating layer 25 is disposed on the lower surface of the rear insulating layer 23. The first bonding insulating layer 25 surrounds a side surface of the first pad 43’, through which first bonding insulating layer 25 the lower surface of the first pad 43’ is exposed. The first pad 43’ includes a first pad barrier layer 44, a first pad seed layer 45, and a first pad conductive layer 46’. The first pad conductive layer 46’ may include copper. The first pad conductive layer 46’ may be formed using an electrolytic plating method. In an embodiment, the lower surface of the first bonding insulating layer 25 and the lower surface of the first pad conductive layer 46’ may be formed in substantially the same plane.

A second pad 93’ is disposed on the second substrate 71. The second pad 93’ is connected to the second through-electrode 82. A second bonding insulating layer 88 is disposed on the second substrate 71. The second bonding insulating layer 88 surrounds a side surface of the second pad 93’, and an upper surface of the second pad 93’ is exposed through the second bonding insulating layer 88. The second pad 93’ includes a second pad barrier layer 84’, a second pad seed layer 85’, and a second pad conductive layer 86”. The second pad conductive layer 86” is continuous with or singularly formed with the second conductive layer 86. The second pad conductive layer 86” may include copper. The second pad conductive layer 86” may be formed using an electrolytic plating method. The upper surface of the second bonding insulating layer 88 and the upper surface of the second pad conductive layer 86” may be formed in substantially the same plane.

The first bonding insulating layer 25 and the second bonding insulating layer 88 may include at least two selected from a group consisting of Si, O, N, C, B, P, and H. In an embodiment, the first bonding insulating layer 25 and the second bonding insulating layer 88 may include SiN, SiCN, SiOCN, SiO, or a combination thereof.

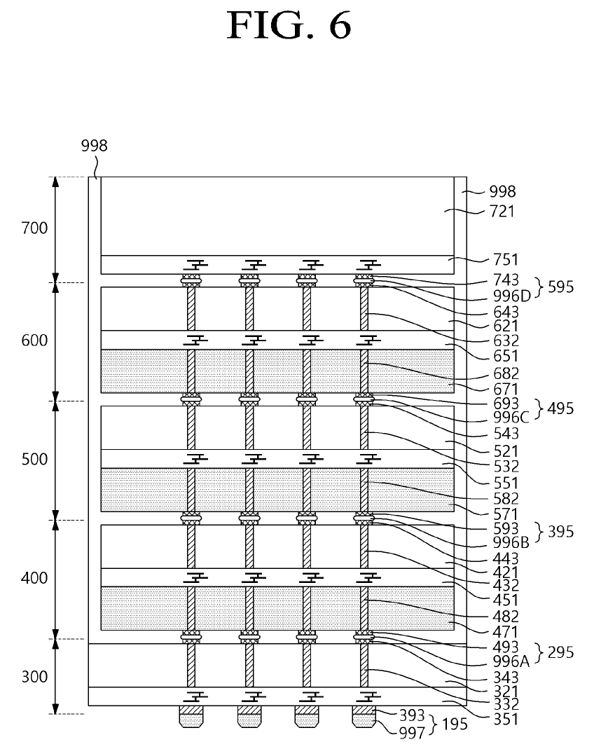

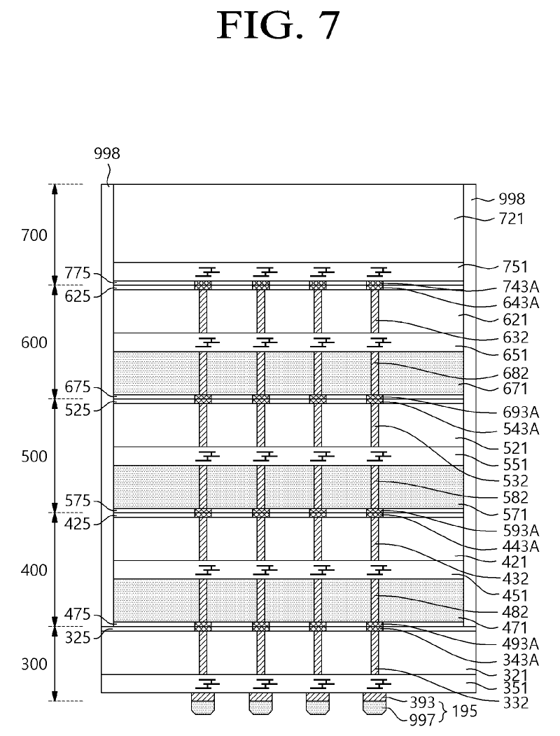

FIGS. 6 and 7 are cross-sectional views illustrating a semiconductor package according to an embodiment of the present disclosure. The semiconductor package according to an embodiment of the present disclosure may be a high bandwidth memory (HBM) package.

Referring to FIG. 6, a semiconductor package according to an embodiment of the present disclosure includes a base chip 300, a first core chip 400, a second core chip 500, a third core chip 600, a top chip 700, and an encapsulation layer 998.

The base chip 300 includes a base substrate 321, a base through-electrode 332, a first base bump 343, a base circuit structure 351, and a second base bump 195.

The base substrate 321 includes a semiconductor substrate such as a silicon wafer. The base circuit structure 351 is be disposed on a lower surface of the base substrate 321. The base circuit structure 351 includes a logic circuit. The base through-electrode 332 extends through the base substrate 321 in a vertical direction and is connected to the base circuit structure 351. The first base bump 343 is disposed on the base substrate 321. The first base bump 343 contacts the base through-electrode 332. The second base bump 195 is disposed on the lower surface of the base circuit structure 351. The second base bump 195 includes a metal pillar 393 and a solder layer 997.

The first core chip 400 is disposed on the base chip 300. The first core chip 400 includes a first core substrate 421, a first core through-electrode 432, a first core bump 443, a first core circuit structure 451, a second core substrate 471, a second core through-electrode 482, and a second core bump 295. The second core bump 295 includes a metal pillar 493 and a solder layer 996A. The solder layer 996A of the second core bump 295 is bonded to the first base bump 343.

The second core chip 500 is disposed on the first core chip 400. The second core chip 500 includes a third core substrate 521, a third core through-electrode 532, a third core bump 543, a second core circuit structure 551, a fourth core substrate 571, a fourth core through-electrode 582, and a fourth core bump 395. The fourth core bump 395 includes a metal pillar 593 and a solder layer 996B. The solder layer 996B of the fourth core bump 395 is bonded to the first core bump 443.

The third core chip 600 is disposed on the second core chip 500. The third core chip 600 includes a fifth core substrate 621, a fifth core through-electrode 632, a fifth core bump 643, a third core circuit structure 651, a sixth core substrate 671, a sixth core through-electrode 682, and a sixth core bump 495. The sixth core bump 495 includes a metal pillar 693 and a solder layer 996C. The solder layer 996C of the sixth core bump 495 is bonded to the third core bump 543.

The top, uppermost, or outermost, chip 700 is disposed on the third core chip 600. The top chip 700 includes a top substrate 721, a top bump 595, and a top circuit structure 751. The top circuit structure 751 is disposed on the lower surface of the top substrate 721. The top bump 595 is disposed on the lower surface of the top circuit structure 751. The top bump 595 includes a metal pillar 743 and a solder layer 996D. The solder layer 996D of the top bump 595 is bonded to the fifth core bump 643.

The encapsulation layer 998 covering the side surfaces of the first core chip 400, the second core chip 500, the third core chip 600, and the top chip 700 is formed on the base chip 300. The encapsulation layer 998 extends to fill spaces between the base chip 300, the first core chip 400, the second core chip 500, the third core chip 600, and the top chip 700. The encapsulation layer 998 may be a molded underfill (MUF) that fills the spaces between the base chip 300, the first core chip 400, the second core chip 500, the third core chip 600, and the top chip 700. As an example, the spaces between the base chip 300, the first core chip 400, the second core chip 500, the third core chip 600, and the top chip 700 are filled with an underfill material that is different from the encapsulation layer 998. As an example, an adhesive layer may be disposed between the encapsulation layers 998 to attach successive semiconductor chips to each other. The encapsulation layer 998 may include an epoxy molding compound. In FIG. 6, three core chips are arranged between the base chip 300 and the top chip 700, although the present disclosure is not limited to this example. One or more core chips are disposed between the base chip 300 and the top chip 700.

Each of the first core chip 400, the second core chip 500, and the third core chip 600 may include substantially the same configuration as described with reference to FIGS. 1 to 4. In an embodiment, each of the second core substrate 471, the fourth core substrate 571, and the sixth core substrate 671 may include substantially the same configurations as the second substrate 71 of FIG. 1. The second core substrate 471, the fourth core substrate 571, and the sixth core substrate 671 may prevent or reduce physical deformation of the first core chip 400, the second core chip 500, and the third core chip 600.

Referring to FIG. 7, a semiconductor package according to an embodiment of the present disclosure includes a base chip 300, a first core chip 400, a second core chip 500, a third core chip 600, a top chip 700, and an encapsulation layer 998.

The base chip 300 includes a base substrate 321, a base bonding insulating layer 325, a base through-electrode 332, a base pad 343A, a base circuit structure 351, and a base bump 195. The base bonding insulating layer 325 is disposed on the base substrate 321. The base bonding insulating layer 325 surrounds the side surface of the base pad 343A, and the upper surface of the base pad 343A is exposed through the base bonding insulating layer 325. The upper surface of the base bonding insulating layer 325 and the upper surface of the base pad 343A may be formed in substantially the same plane.

The first core chip 400 is disposed on the base chip 300. The first core chip 400 includes a first core substrate 421, a first core bonding insulating layer 425, a first core through-electrode 432, a first core pad 443A, a first core circuit structure 451, a second core substrate 471, a second core bonding insulating layer 475, a second core through-electrode 482, and a second core pad 493A.

The second core bonding insulating layer 475 is disposed on the lower surface of the second core substrate 471. The second core bonding insulating layer 475 surrounds the side surface of the second core pad 493A and the lower surface of the second core pad 493A is exposed through the second core bonding insulating layer 475. The lower surface of the second core bonding insulating layer 475 and the lower surface of the second core pad 493A may be formed in substantially the same plane. The second core bonding insulating layer 475 is bonded to the base bonding insulating layer 325. The second core pad 493A is bonded to the base pad 343A.

The first core bonding insulating layer 425 is disposed on the first core substrate 421. The first core bonding insulating layer 425 surrounds a side surface of the first core pad 443A, and an upper surface of the first core pad 443A is exposed through the first core bonding insulating layer 425. The upper surface of the first core bonding insulating layer 425 and the upper surface of the first core pad 443A may be formed in substantially the same plane.

The second core chip 500 is disposed on the first core chip 400. The second core chip 500 includes a third core substrate 521, a third core bonding insulating layer 525, a third core through-electrode 532, a third core pad 543A, a second core circuit structure 551, a fourth core substrate 571, a fourth core bonding insulating layer 575, a fourth core through-electrode 582, and a fourth core pad 593A.

The fourth core bonding insulating layer 575 is disposed on a lower surface of the fourth core substrate 571. The fourth core bonding insulating layer 575 surrounds a side surface of the fourth core pad 593A, and a lower surface of the fourth core pad 593A is exposed through the fourth core bonding insulating layer 575. The lower surface of the fourth core bonding insulating layer 575 and the lower surface of the fourth core pad 593A may be formed in substantially the same plane. The fourth core bonding insulating layer 575 is bonded to the first core bonding insulating layer 425. The fourth core pad 593A is bonded to the first core pad 443A.

The third core bonding insulating layer 525 is disposed on the third core substrate 521. The third core bonding insulating layer 525 surrounds the side surface of the third core pad 543A, and the upper surface of the third core pad 543A is exposed through the third core bonding insulating layer 525. The upper surface of the third core bonding insulating layer 525 and the upper surface of the third core pad 543A may be formed in substantially the same plane.

The third core chip 600 is disposed on the second core chip 500. The third core chip 600 includes a fifth core substrate 621, a fifth core bonding insulating layer 625, a fifth core through-electrode 632, a fifth core pad 643A, a third core circuit structure 651, a sixth core substrate 671, a sixth core bonding insulating layer 675, a sixth core through-electrode 682, and a sixth core pad 693A.

The sixth core bonding insulating layer 675 is disposed on the lower surface of the sixth core substrate 671. The sixth core bonding insulating layer 675 surrounds the side surface of the sixth core pad 693A, and the lower surface of the sixth core pad 693A is exposed by the sixth core bonding insulating layer 675. The lower surface of the sixth core bonding insulating layer 675 and the lower surface of the sixth core pad 693A may be formed in substantially the same plane. The sixth core bonding insulating layer 675 is bonded to the third core bonding insulating layer 525. The sixth core pad 693A is bonded to the third core pad 543.

The fifth core bonding insulating layer 625 is disposed on the fifth core substrate 621. The fifth core bonding insulating layer 625 surrounds the side surface of the fifth core pad 643A, and the upper surface of the fifth core pad 643A is exposed through the fifth core bonding insulating layer 625. The upper surface of the fifth core bonding insulating layer 625 and the upper surface of the fifth core pad 643A may be formed in substantially the same plane.

The top, uppermost, or outermost, chip 700 is disposed on the third core chip 600. The top chip 700 includes a top substrate 721, a top pad 743A, a top circuit structure 751, and a top bonding insulating layer 775. The top bonding insulating layer 775 is disposed on a lower surface of the top circuit structure 751. The top bonding insulating layer 775 surrounds a side surface of the top pad 743A, and a lower surface of the top pad 743A is exposed through the top bonding insulating layer 775. The lower surface of the top bonding insulating layer 775 and the lower surface of the top pad 743A may be formed in substantially the same plane. The top bonding insulating layer 775 is bonded to a fifth core bonding insulating layer 625. The top pad 743A is bonded to the fifth core pad 643A.

The encapsulation layer 998 covering the side surfaces of the first core chip 400, the second core chip 500, the third core chip 600, and the top chip 700 is disposed on the base chip 300. In FIG. 7, three core chips are disposed between the base chip 300 and the top chip 700, although embodiments of the present disclosure are not limited to this example. One or more core chips may be disposed between the base chip 300 and the top chip 700.

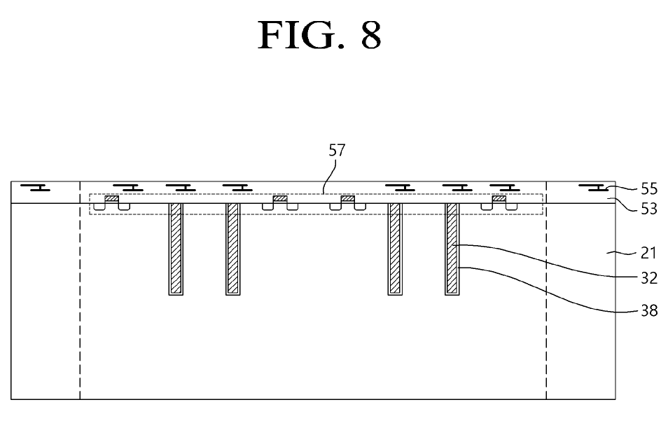

FIGS. 8 to 19 are cross-sectional views of a semiconductor package according to an embodiment of the present disclosure according to a process sequence.

Referring to FIG. 8, a first through-electrode 32 is formed within the first substrate 21. An interlayer insulating layer 53, a plurality of horizontal/vertical wirings 55, and an integrated circuit 57 are formed on the first substrate 21. A first spacer 38 surrounds a side of the first through-electrode 32.

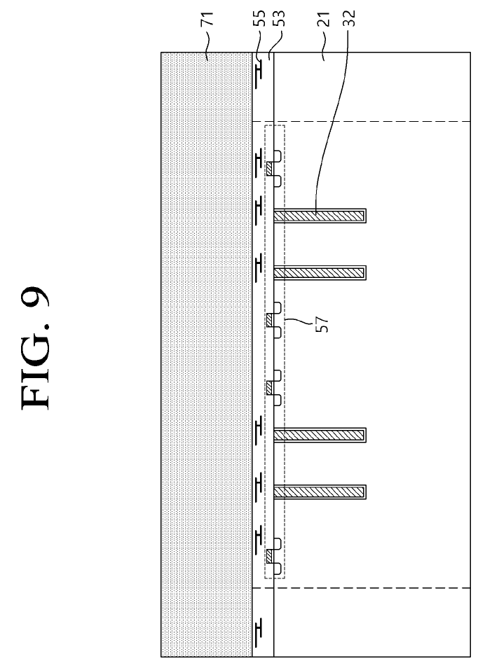

Referring to FIG. 9, a second substrate 71 is formed on the interlayer insulating layer 53. In an embodiment, the second substrate 71 is formed having substantially the same configuration as described with reference to FIGS. 1 to 4. In an embodiment, the second substrate 71 may include an inorganic insulating material. The inorganic insulating film may include silicon nitride, silicon oxide, or a combination thereof. The second substrate 710 may be formed using a chemical vapor deposition (CVD) method. The process of forming the second substrate 71 may include a low-temperature deposition process performed in an atmosphere at a temperature of 350°C or lower. The process of forming the second substrate 71 may include a coating process. A thickness of the second substrate 71 in the first direction is less than or equal to a height of the first through-electrode 32.

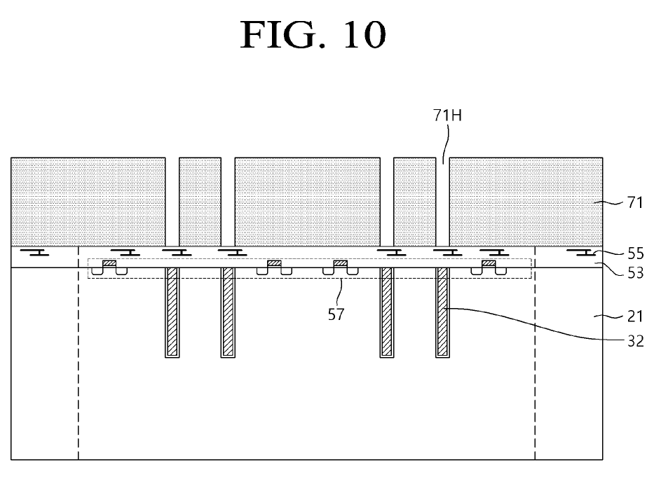

Referring to FIG. 10, through-holes 71H that vertically extend through the second substrate 71 are formed. The through-holes 71H overlap or align with the first through-electrodes 32 in the vertical direction. The process of forming the through-hole 71H may vary depending on the type of material in the second substrate 71. When the second substrate 71 includes an inorganic insulating material, forming the through-hole 71H may include a photolithography and an etching process.

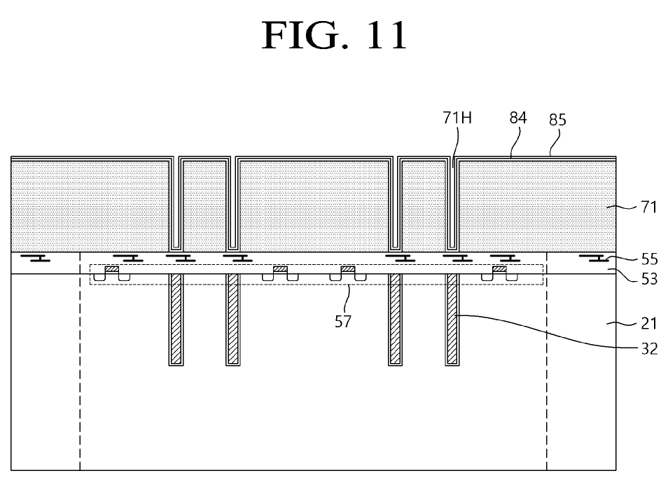

Referring to FIG. 11, a second barrier layer 84 is formed to cover inner walls of the the second substrate 71 adjacent to the through-holes 71H and an upper surface of the second substrate 71. A second seed layer 85 is formed on the second barrier layer 84. The second barrier layer 84 and the second seed layer 85 may be formed by a physical vapor deposition (PVD) process.

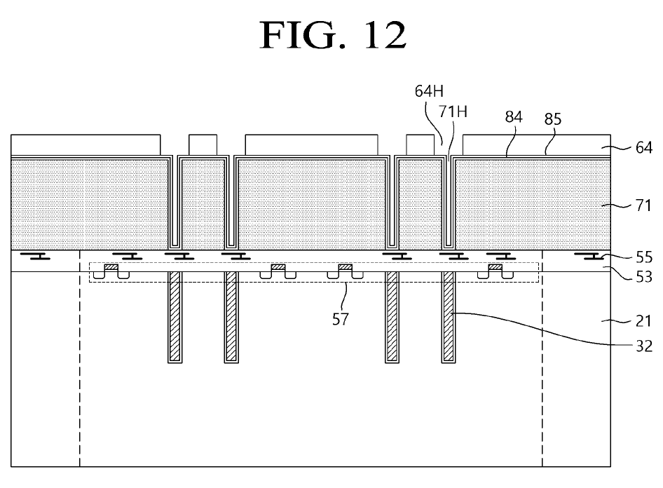

Referring to FIG. 12, a mask pattern 64 having an opening 64H is formed on a second seed layer 85. The opening 64H overlaps or aligns with the through-hole 71H in a vertical direction. The openings 64H are adjacent to the through-holes 71H.

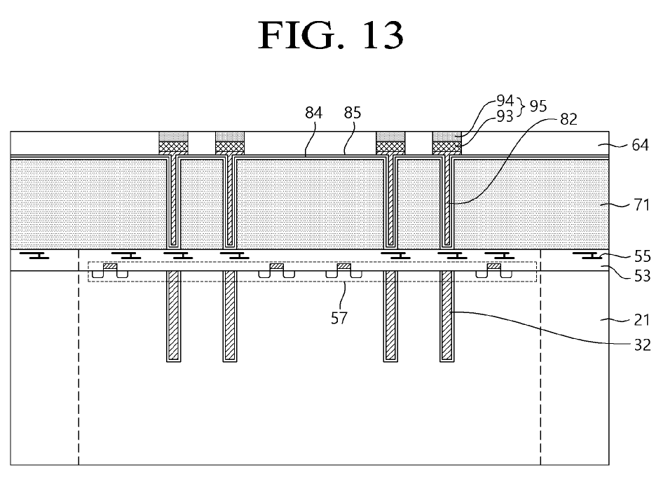

Referring to FIG. 13, a second bump 95 is formed in the opening 64H, and a second through-electrode 82 is formed in the through-hole 71H. The second bump 95 includes a metal pillar 93 and a solder layer 94. In an embodiment, the second through-electrode 82 and the second bump 95 include the same configuration as described with reference to FIG. 2. The second through-electrode 82 and the second bump 95 may be formed by an electrolytic plating process.

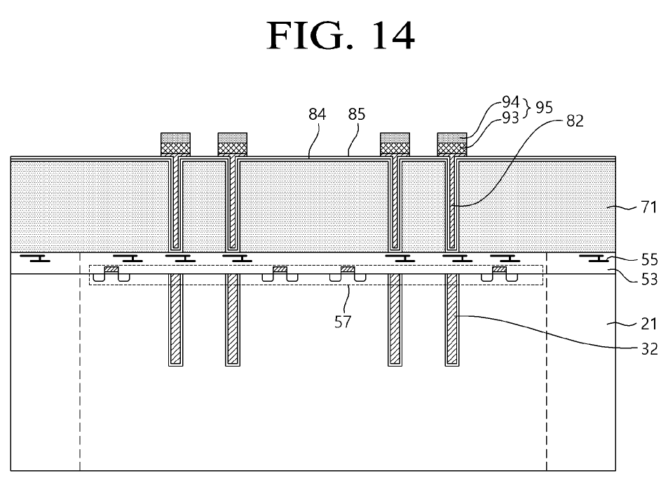

Referring to FIG. 14, the mask pattern 64 is removed.

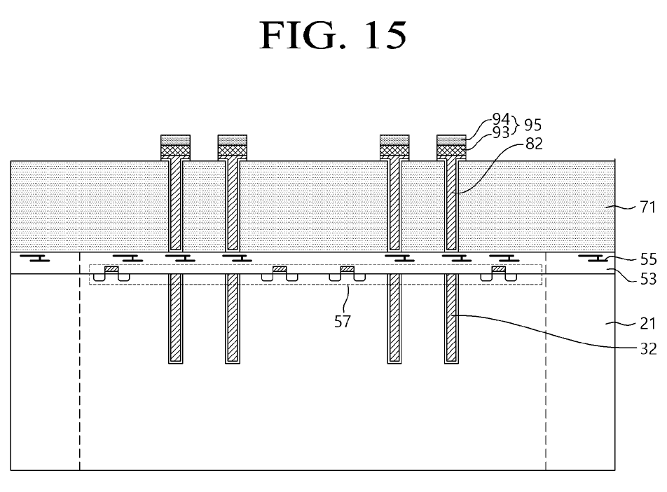

Referring to FIG. 15, the second seed layer 85 of FIG. 14 and the second barrier layer 84 of FIG. 14, exposed by removal of the mask pattern 64, are removed. The upper surface of the second substrate 71 that does not vertically overlap with the second bump 95 is exposed.

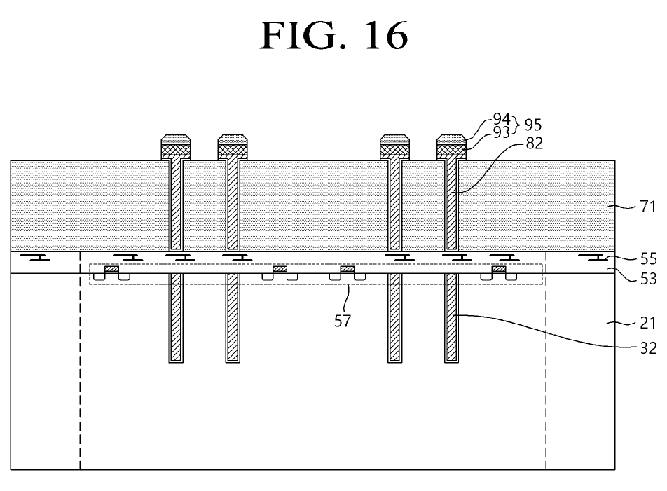

Referring to FIG. 16, the solder layer 94 is reflowed using a heat treatment process. Accordingly, the surface of the solder layer 94 may be formed having a round shape.

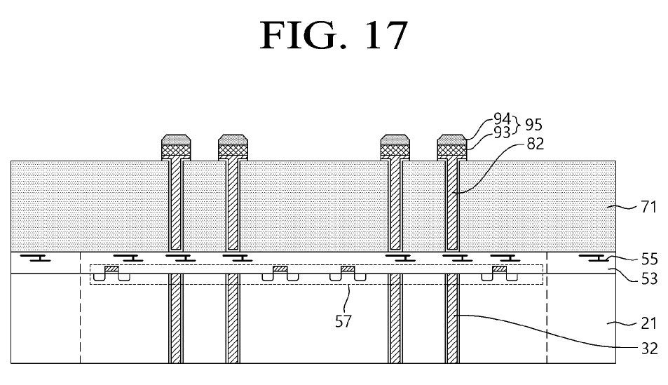

Referring to FIG. 17, the lower section of the first substrate 21 is removed to expose the lower ends of the first through-electrodes 32. The lower section of the first substrate 21 may be removed by a back-grinding process.

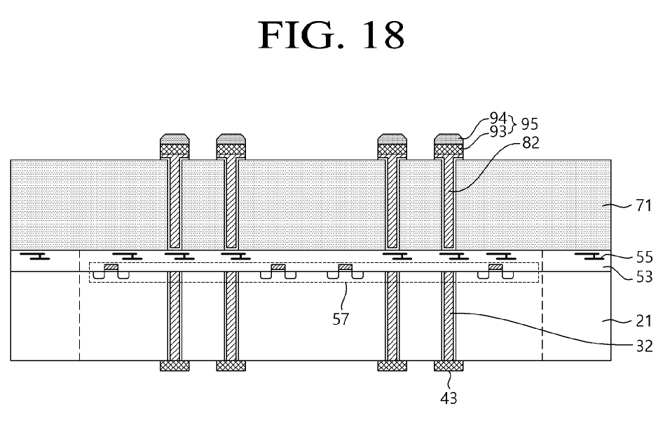

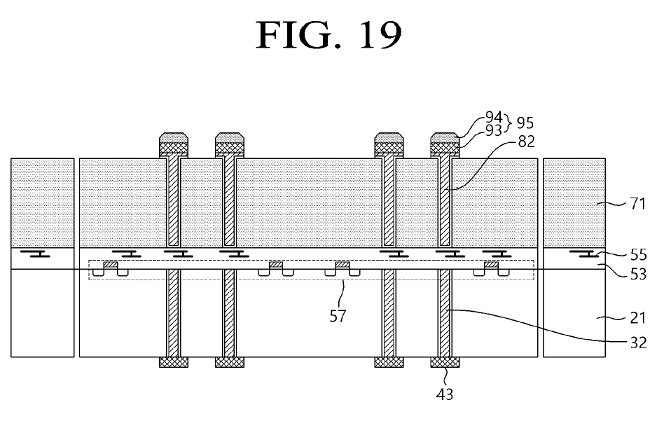

Referring to FIG. 18, a first bump 43 is formed on a lower surface of the first substrate 21. The first bump 43 contacts the first through-electrode 32. The first bump 43 includes a first bump barrier layer, a first bump seed layer, and a first bump conductive layer that are sequentially stacked. Referring to FIG. 19, a semiconductor chip may be separated using a singulation process.

Although not shown, a plurality of semiconductor chips are stacked to form a semiconductor package. When stacking semiconductor chips, a second bump of an upper semiconductor chip is bonded to a first bump of a lower semiconductor chip.

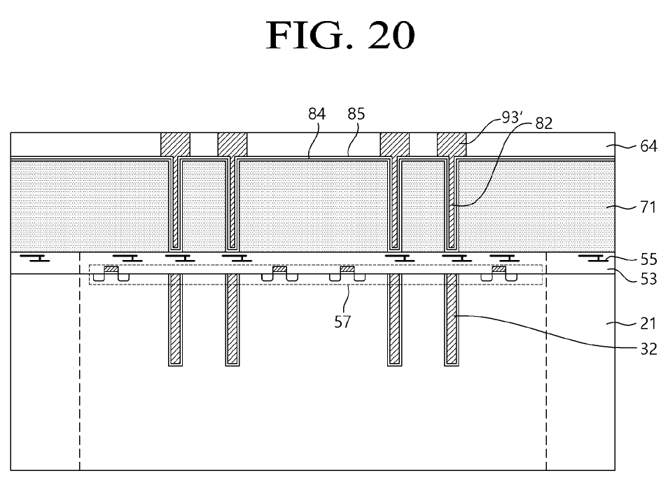

FIGS. 20 to 26 are cross-sectional views of a semiconductor package formed utilizing a method of forming a semiconductor chip and a semiconductor package according to an embodiment of the present disclosure.

Referring to FIG. 20, a second pad 93’ is formed in an opening 64H of FIG. 12, and a second through-electrode 82 is formed in a through-hole 71H of FIG. 12. In an embodiment, the second through-electrode 82 and the second pad 93’ include the same configuration as described with reference to FIG. 5. The second through-electrode 82 and the second pad 93’ may be formed by an electrolytic plating process.

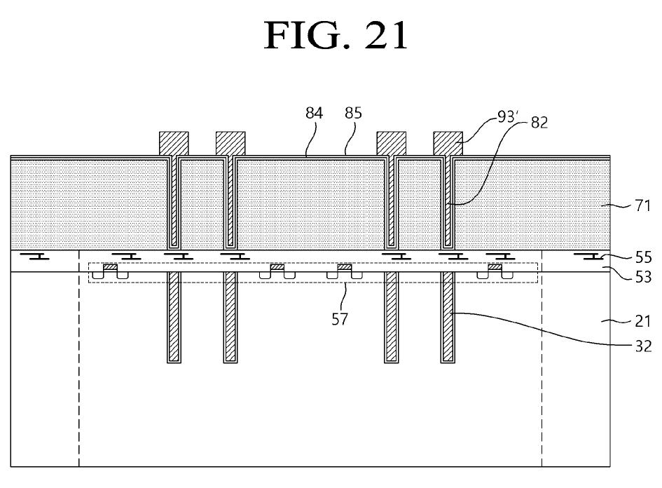

Referring to FIG. 21, the mask pattern 64 is removed.

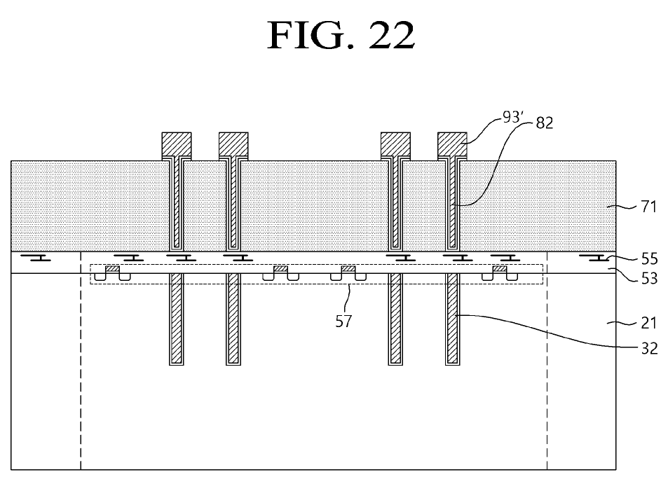

Referring to FIG. 22, the second seed layer 85 of FIG. 21 and the second barrier layer 84 of FIG. 21 exposed by removal of the mask pattern 64 are removed, thereby exposing the upper surface of the second substrate 71.

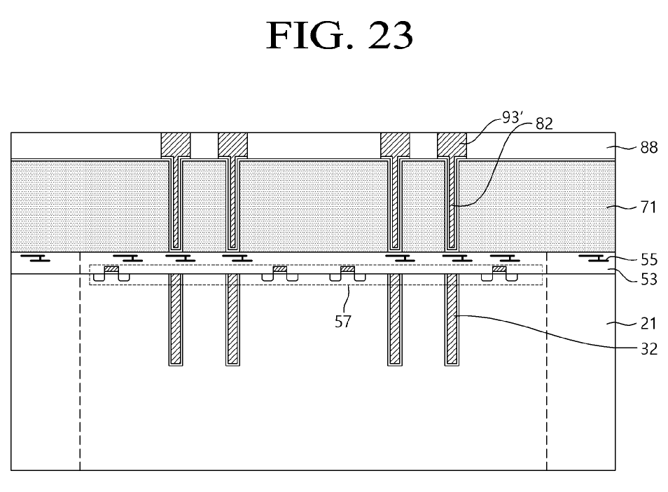

Referring to FIG. 23, a second bonding insulating layer 88 is formed on the upper surface of the second substrate 71.

The second bonding insulating layer 88 surrounds the side surfaces of the second pads 93’, and the upper surface of the second pad 93’ is exposed through the second bonding insulating layer 88. The upper surface of the second bonding insulating layer 88 and the upper surface of the second pad 93’ may be formed in substantially the same plane. Forming the second bonding insulating layer 88 includes forming an insulating layer on the upper surface of the first substrate 71 and the second pad 93’ and polishing the insulating layer to expose the second pad 93’. Polishing the insulating layer may include a chemical mechanical polishing (CMP) process.

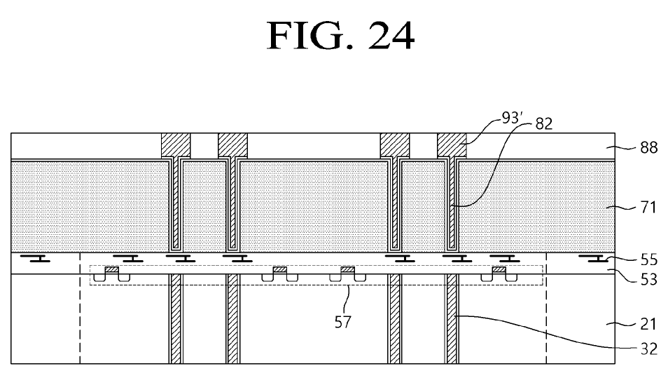

Referring to FIG. 24, the lower section of the first substrate 21 is removed to expose the lower ends of the first through-electrodes 32. The lower section of the first substrate 21 may be removed by a back-grinding process.

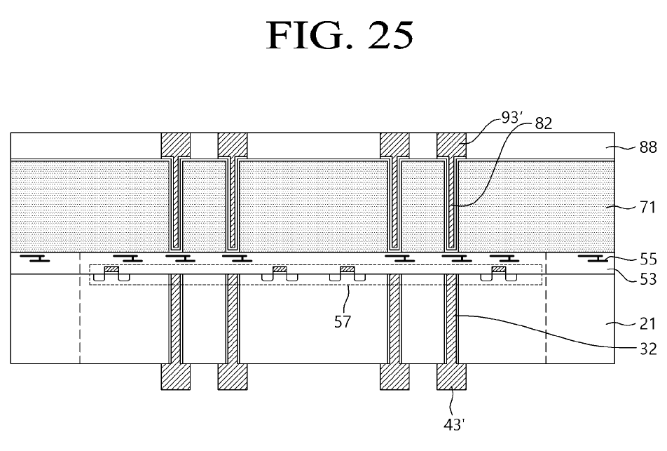

Referring to FIG. 25, a first pad 43’ is formed on the lower surface of the first substrate 21. The first pad 43’ is connected to the first through-electrode 32. The first pad 43’ may include the same configuration as described with reference to FIG. 5.

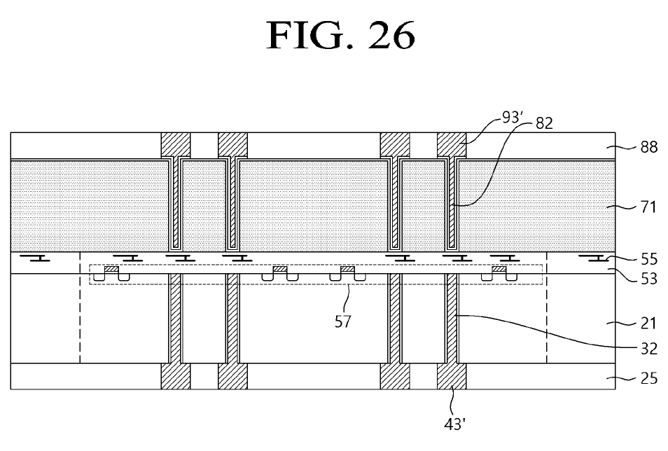

Referring to FIG. 26, a first bonding insulating layer 25 is formed on the lower surface of the first substrate 21.

The first bonding insulating layer 25 surrounds the side surface of the first pad 43’, and the lower surface of the first pad 43’ is exposed through the first bonding insulating layer 25. The lower surface of the first bonding insulating layer 25 and the lower surface of the first pad 43’ may be formed in substantially the same plane.

Forming the first bonding insulating layer 25 includes forming an insulating layer on the lower surface of the first substrate 71 and the first pad 25 and may including polishing the insulating layer to expose the first pad 25. Polishing the insulating layer may include a CMP process.

Although not shown, semiconductor chip are separated using a singulation process. A plurality of semiconductor chips manufactured as described are stacked to form a semiconductor package. When stacking semiconductor chips, a second bonding insulating layer of an upper semiconductor chip is bonded to a first bonding insulating layer of a lower semiconductor chip, and a second pad of the upper semiconductor chip is bonded to a first pad of the lower semiconductor chip.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor chip comprising:
a first substrate having a first coefficient of thermal expansion;
a circuit structure on the first substrate; and
a second substrate disposed on the circuit structure and having a second coefficient of thermal expansion in a range of 0.8 to 1.2 times the first coefficient of thermal expansion.

2. The semiconductor chip of claim 1, wherein the first coefficient of thermal expansion of the first substrate is 2.5 ppm/℃ to 3.6 ppm/℃, and the second coefficient of thermal expansion of the second substrate is 2.0 ppm/℃ to 4.3 ppm/℃.

3. The semiconductor chip of claim 1, wherein the second substrate has a thickness ranging from 0.2 to 1.2 times a thickness of the first substrate.

4. The semiconductor chip of claim 1, wherein each of the first substrate and the second substrate has a thickness larger than a thickness of the circuit structure,
wherein the second substrate has substantially the same thickness as the first substrate.

5. The semiconductor chip of claim 1, wherein the first substrate includes single crystal silicon; and
wherein the second substrate includes silicon nitride, silicon oxide, or a combination thereof.

6. The semiconductor chip of claim 1, further comprising a first through-electrode that extends through the first substrate and is connected to the circuit structure.

7. The semiconductor chip of claim 6, further comprising a second through-electrode that extends through the second substrate and is connected to the circuit structure.

8. The semiconductor chip of claim 7, wherein the second through-electrode overlaps with the first through-electrode in a first direction.

9. A semiconductor package comprising:
a base chip;
a core chip on the base chip; and
a top chip on the core chip;
wherein the core chip comprises:
a first substrate having a first coefficient of thermal expansion;
a circuit structure on the first substrate; and
a second substrate disposed on the circuit structure and having a second coefficient of thermal expansion in a range of 0.8 to 1.2 times the first coefficient of thermal expansion.

10. The semiconductor package of claim 9, wherein the first coefficient of thermal expansion of the first substrate is 2.5 ppm/℃ to 3.6 ppm/℃, and the second coefficient of thermal expansion of the second substrate is 2.0 ppm/℃ to 4.3 ppm/℃.

11. The semiconductor package of claim 9, wherein the second substrate has a thickness ranging from 0.2 to 1.2 times a thickness of the first substrate.

12. The semiconductor package of claim 9, wherein the first substrate includes single crystal silicon; and
wherein the second substrate includes silicon nitride, silicon oxide, or a combination thereof.

13. The semiconductor package of claim 9, wherein the core chip further comprises:
a first through-electrode that extends through the first substrate and is connected to the circuit structure; and
a second through-electrode that extends through the second substrate and is connected to the circuit structure.

14. The semiconductor package of claim 13, wherein the second through-electrode overlaps with the first through-electrode in a first direction.

15. The semiconductor package of claim 9, further comprising an encapsulation layer covering a side surface of the core chip and a side surface of the top chip.

16. The semiconductor package of claim 9, wherein the encapsulation layer extends between the base chip and the core chip and between the core chip and the top chip.

17. A semiconductor package comprising:
a plurality of semiconductor chips stacked sequentially, wherein each of the plurality of semiconductor chips comprises:
a first substrate having a first coefficient of thermal expansion;
a circuit structure on the first substrate; and
a second substrate disposed on the circuit structure and having a second coefficient of thermal expansion in a range of 0.8 to 1.2 times the first coefficient of thermal expansion.

18. The semiconductor package of claim 17, wherein the first coefficient of thermal expansion of the first substrate is 2.5 ppm/℃ to 3.6 ppm/℃, and the second coefficient of thermal expansion of the second substrate is 2.0 ppm/℃ to 4.3 ppm/℃.

19. The semiconductor package of claim 17, wherein the second substrate has a thickness ranging from 0.2 to 1.2 times a thickness of the first substrate.

20. The semiconductor package of claim 17, wherein the first substrate includes single crystal silicon; and
wherein the second substrate includes silicon nitride, silicon oxide, or a combination thereof.
